(19) United States
(12) Patent Application Publication
(10) Pub. No.: US 2002/0023590 A1
(43) Pub. Date: Feb. 28, 2002

(54) Susceptor for semiconductor wafers

(76) Inventor: Olaf Storbeck, Dresden (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 09/941,824

(22) Filed: Aug. 29, 2001

(30) Foreign Application Priority Data
Aug. 29, 2000 (EP) 00118670.9

(51) Int. Cl. C23C 16/00

(52) U.S. Cl. 118/725

(57) ABSTRACT

A wafer chuck for semiconductor wafer manufacturing has a surface for the accommodation of a semiconductor wafer. The surface has a concave shape. The wafer, especially with a diameter of more than 300 mm, normally has a concave or convex warpage according to tensile strength from deposited layers. By appropriate size of the concaveness of the chuck surface the perimeter edge of the wafer always touches the hot surface of the chuck first, so that the wafer is flattened, thereby avoiding a movement of the wafer on the hot chuck surface.

### BACKGROUND OF THE INVENTION

### FIELD OF THE INVENTION

The invention lies in the semiconductor technology field. More specifically, the invention pertains to a susceptor for a semiconductor wafer.

In the field of semiconductor wafer manufacturing typical processing steps comprise CVD (Chemical Vapor Deposition), dry etching, sputtering, PVD (Physical Vapor Deposition), and the like. In such processes the wafer is located on a wafer susceptor, a so-called wafer chuck. The wafer resides on the chuck with its back side, whereby the front side is subject to the application of reaction gases or physical/chemical treatment by the environment within the process chamber. In all of the above-mentioned processes it is necessary to heat the wafer through the chuck.

Semiconductor wafers are usually warped. The warpage is caused by one or multiple layers on the front side of the wafer which exert a tensile force on the wafer. The wafer is warped either concavely or convexly when seen from its front side. Especially when the wafer is warped concavely, the warpage will be increased when the wafer is placed on a hot chuck in a process chamber. This is due to the fact that the center of the wafer is heated first, thereby expanding the center portion of the semiconductor material so that the concave warpage is amplified. This often causes a moving or jumping of the wafer immediately after it is placed on the chuck. Wafer warpage is an especial problem with wafers having a diameter of more than 200 mm (millimeter) (10 inch wafers) and especially with wafer diameters of 300 mm and more.

U.S. Pat. No. 5,872,694 shows an electrostatic chuck with a pedestal and a recess in order to measure wafer warpage. U.S.

Pat. No. 6,025,099 shows a smoothly curved chuck for an exposure tool with a vacuum channel that sucks the plane wafer to the chuck to provide a bow-shaped wafer to improve light exposure.

### SUMMARY OF THE INVENTION

It is an object of the invention to provide a susceptor for semiconductor wafers, which overcomes the above-mentioned disadvantages of the heretofore-known devices and methods of this general type and which avoids a movement of the wafer when it is placed on the susceptor.

With the foregoing and other objects in view there is provided, in accordance with the invention, a susceptor for supporting a semiconductor wafer, i.e., a substrate support apparatus for supporting a substrate in a processing chamber.

The susceptor comprises:

a surface for supporting a semiconductor wafer, the surface having a concave shape; and

a heater thermally coupled to the surface for heating the surface.

In other words, the surface onto which the wafer can be placed has a concave shape, and a heating means is thermally coupled to the surface for heating the surface.

The susceptor according to the invention has a surface for the accommodation of the semiconductor wafer, preferably a silicon wafer, which has a concave shape. With the concave shape of the susceptor surface any movement of the wafer is avoided, especially when the chuck is hot.

According to the concave shape of the surface a plane which is defined by an outer circle of the surface surrounding the center portion of that surface has a distance from the center of the surface. The distance between the circle with the largest diameter and the center is characteristic for the concave shape of the chuck. The distance should be more than 200 μm (micrometer). Preferably the distance is larger than 500 μm, especially when the chuck is designed for 300 mm wafers. For wafers with a diameter larger than 300 mm the distance can be considerably larger than 500 μm. The characteristic distance between the plane which is defined by the largest circle of the chuck surface and the center of the surface should be such that a wafer having the largest possible warpage touches the surface of the chuck with its circumference. It is to be avoided that the wafer has the first contact with the chuck through its center portion. When touching the hot surface of the chuck with its circumference, the outer portion of the wafer is heated first, so that it extends outwardly and thereby flattens the wafer. Thereby the chuck must be sufficiently concave in form so that each wafer irrespective of its bowing or warpage always touches the chuck at its perimeter first. The above function both applies to wafers which are bowed concavely and wafers which are bowed convexly with respect to the wafer's front side.

For a hot chuck as for the application in process chambers for CVD, dry etch, sputter, and PVD the susceptor is made of metal. Any type of metal suitable for such processes is acceptable. Preferred metals can be aluminum or titanium.

The chuck is coupled to a heating means which can heat the chuck up to 400° C. It is also conceivable that the chuck is heated up to more than 400° C. Any type of known heating method can be applied, e.g. electrical heating or heating by infrared lamps. Since the problem of wafer bowing becomes especially relevant in the semiconductor industry with 300 mm silicon wafers, the invention is preferably applied to 300 mm wafer production.

The surface of the chuck can be structured in any known way. The surface may be smooth or may be provided with concentric, projecting rings. The chuck can be provided with any other type of structure. Also, any type of known means for holding the wafer is acceptable, e.g. provisions for clamping the wafer. Further, holes for the application of a vacuum within the surface of the chuck can be provided at the chuck's surface. When the chuck is structured it is to be noted that the concave shape applies to the envelope curve of the surface.

Other features which are considered as characteristic for the invention are set forth in the appended claims.

Although the invention is illustrated and described herein as embodied in a susceptor for semiconductor wafers, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1A is a sectional side view of a chuck according to the invention with a concave surface before a concave wafer is placed onto the chuck;

FIG. 1B is a similar view thereof, after placement of the wafer and after reaching thermal equilibrium;

FIG. 2A is a sectional side view of the chuck according to the invention with the concave surface prior to receiving thereon a convexly bowed wafer;

FIG. 2B is similar view thereof, after placement of the wafer and after reaching thermal equilibrium; and

FIG. 3 is a partial sectional view of a chuck according to the invention in an alternative embodiment of the support surface.

### DESCRIPTION OF THE PREFERRED EMBODIMENTS

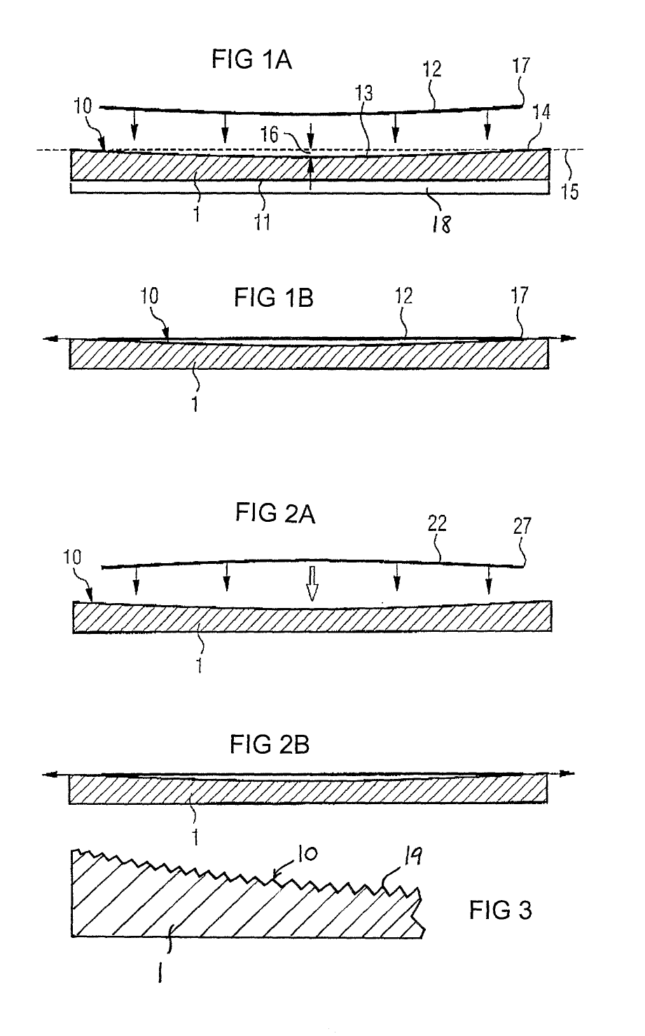

Referring now to the figures of the drawing in detail and first, particularly, to FIG. 1 thereof, a chuck 1 has an upper surface 10 which is provided to receive a wafer 12. A bottom side 11 of the chuck is shown as a plane surface for simplification purposes. However, there are arbitrary shapes possible for the bottom side 11 of the chuck 1. A planar heater 18 is diagrammatically illustrated in FIG. 1A only. Additional structure, such as supporting means to fix the chuck within a process chamber, for example, is not illustrated for purposes of clarity.

The upper surface 10 of the chuck has a concave shape. This means that the outer portion 14 of the chuck is higher than the center portion 13. The chuck 1 has a circular shape. A circle on the surface 10 through the outer portion 14 defines a plane 15. The distance 16 between the plane 15 and the center 13 is characteristic for the concave shape of the surface 10 of the chuck. The wafer 12 to be placed onto the chuck has a diameter of 300 mm in the illustrated embodiment. A distance 16 for a 300 mm wafer is preferably 500 μm or more. The distance 16 should be larger than the greatest possible bowing of the wafer 12.

As shown in FIG. 1B the wafer 12 is flattened. This is due to the fact that the perimeter 17 of the wafer touches the surface 10 of the chuck first irrespective of the amount of bowing of the wafer. Since the chuck is heated to a temperature between 300° C. and 400° C., or more than 400° C., the perimeter 17 of the wafer 12 is subjected to the heat transfer first. As a result, the outer portion of the silicon material of the wafer 12 is heated first and expands and generates a force pulling outwardly within the silicon material. As a result the wafer 12 is flattened after an appropriate time period when placed onto the chuck. Thereby any jumping of the wafer, which may happen when a 300 mm wafer is placed on a hot chuck with a flat surface, is avoided. The flat state of the wafer is reached latest when thermal equilibrium is established.

In FIG. 2 the chuck 1 is the same as in FIG. 1. The wafer 22 to be placed onto the chuck 1 has a convex bowing shape with respect to its front side. The back side of the wafer 22 is placed onto the concave surface 10 of the chuck 1. As with the concave shaped wafer 12 of FIG. 1, the convex shaped wafer 22 of FIG. 2 also touches the surface 10 of the chuck 1 at its perimeter 27. The hot chuck 1 heats up the outer portion of the wafer 22 first so that an outwardly pulling force within the silicon material of the wafer 22 is generated which flattens the wafer until it reaches the equilibrium state.

In any case, the chuck is designed so that the wafer 12, 22 establishes its thermal contact with the surface 10 of the chuck 1 at its perimeter edge only. The difference spacing 16 for the chuck 1 should preferably be in the range of 500 μm for silicon wafers having a diameter of 300 mm.

The chuck 1 has heating means attached to its bottom interface 11 which provide sufficient heat to the chuck. Preferably, the chuck surface 10 provides a heat of 400° C. or slightly more to the wafer 12, 22. The surface 10 of the chuck 1 may have concentric circles which are projecting. Any other suitable microstructure of the surface 10 of the chuck is possible.

The surface 10 of the chuck may have any smooth bow-shaped form that fulfills the above-outlined requirements. The surface 10 should be always close to the backside of the wafer, but there must be sufficient distance between the wafer backside and the chuck surface so that the wafer does not ever, in any case, touch the chuck, irrespective of the degree of bowing. Preferably the macroscopic surface or envelope of the surface of the wafer should not include any steps. The macroscopic surface or the envelope surface of the chuck has a continuous form, i.e. it does not have any steps. Many continuous bow-shaped forms fulfilling the above-mentioned requirements are conceivable. One example of a shape would be a spherical surface. It is also possible that the surface 10 is part of a parabolic or hyperbolic three-dimensional surface. The surface 10 of the chuck is smoothly recessed without a step when travelling from the outer circumference of the chuck towards its center. Thus, the wafer is only in contact with the chuck's surface at the wafer edge. Only the perimeter of the wafer is in contact with the surface of the chuck.

With reference to FIG. 3, the top surface 10 of the chuck 1 may be structured, for example, formed with a plurality of concentric, projecting rings 19. The wafer 12 then sits on the apex of the rings, as seen in cross-section, which define the envelope of the structured surface. It should be understood that the concave shape refers to envelope curve of the surface structure.

I claim:

1. A susceptor for supporting a semiconductor wafer, comprising:
a surface for supporting a semiconductor wafer, said surface having a concave shape; and
a heater thermally coupled to said surface for heating said surface.

2. The susceptor according to claim 1, wherein said surface has a center portion and an outer portion surrounding said center portion, and wherein a distance between said center portion and a plane defined by a circle along said outer portion is greater than 200 μm.

3. The susceptor according to claim 2, wherein said distance is greater than 500 μm.

4. The susceptor according to claim 2, wherein said circle is defined with a diameter of substantially 300 mm.

5. The susceptor according to claim 1, wherein said susceptor is formed of metal.

6. The susceptor according to claim 1, wherein said heater is configured to heat the wafer to a temperature of at least 400° C.

7. The susceptor according to claim 1 configured to carry a silicon wafer with a diameter of at least 300 mm.

8. The susceptor according to claim 1, wherein said surface is formed with a plurality of concentric, projecting rings.
